(19) United States
(12) Patent Application Publication
(10) Pub. No.: US 2023/0347186 A1
(43) Pub. Date: Nov. 2, 2023

(54) INTEGRATED DISPLAY FOR SEALED FACE MASKS

(71) Applicant: Federal Express Corporation, Memphis, TN (US)

(72) Inventors: Nathan Klatt, Dublin, CA (US); Jean-Claude de Sugny, San Francisco, CA (US); Michael Huynh, San Francisco, CA (US); Kevin Ferguson, Concord, CA (US); Divya Prasannan, Dublin, CA (US)

(21) Appl. No.: 17/730,774

(22) Filed: Apr. 27, 2022

(51) Int. Cl. A62B 18/08; G02F 1/1362; H05K 7/20; H05K 9/00; G02B 27/01; A62B 18/04; A62B 7/02; G09G 3/00

(52) U.S. Cl. CPC A62B 18/082; G02F 1/136277; H05K 7/209; H05K 9/0081; G02B 27/0176; A62B 18/04; A62B 7/02; G09G 3/002; G02B 2027/0159; G09G 2320/0626

(57) ABSTRACT

This disclosure involves systems and an apparatus for an in-mask display and mounting system for a display to be integrated into a positive pressure mask. In certain enclosed environments, emergency masks are used as a backup source of breathable atmosphere in the event the regular atmosphere becomes unusable. While the mask may enable breathing, smoke or other environmental factors may inhibit visibility. This disclosure provides an in-mask display, and mounting system to provide critical information to the user, regardless of visibility external to the mask. A mechanism is provided to allow the display to be translated vertically within the mask, allowing the user to align the display with their eyes. The display must also be mounted in a manner that minimizes mask penetrations and rejects any heat generated by the display outside of the mask.

### BACKGROUND

Positive pressure face masks can ensure supply of breathable gas is present in the event the ambient atmosphere becomes unbreathable. For example, a fire in a contained environment such as an aircraft or submarine can rapidly render the atmosphere unbreathable. In addition to being unbreathable, smoke can hinder visibility.

### SUMMARY

The present disclosure encompasses systems, methods, and an apparatus for providing a display inside a sealed face mask. In general, innovative aspects of the subject matter described in this specification can be embodied a visual display mounting system. The mounting system is configured for mounting a visual display system inside full-face masks and includes a mount and a chassis. The mount includes a first plate and a second plate configured to be attached to a full-face mask. The first plate is configured to be attached externally to a top of the full-face mask, and the second plate is shaped to fit inside the full-face mask. The first plate and second plate are configured to be coupled one to the other through a frame of the full-face mask. The chassis is configured to be suspended from the second plate, when installed in the full-face mask. The chassis supports display optics and electronic circuitry of the visual display system. This and other implementations can each optionally include one or more of the following features.

In some implementations, the chassis is suspended from the second plate by a drive screw and a guide rod. The guide rod can be configured to conduct thermal energy from the electronic circuitry to a fastener in the second plate.

In some implementations, the fastener in the second plate is configured to conduct thermal energy to the first plate.

In some implementations, the visual display system includes a printed circuit board (PCB), one or more light sources, liquid-crystal-on-silicon (LCOS) displays, and partial reflectors enclosed in a metal housing, and the PCB includes a protruding edge in physical contact with and electrically grounded to the metal housing.

Another general aspect can be embodied in a device that includes a full-face mask and a video display system placed inside the full-face mask. The full-face mask is configured to seal against a user's face, when in use, to form a mask cavity, and the mask includes a built-in respirator and a transparent face shield. The visual display system includes display optics and electronic circuitry held in a chassis suspended from a mount secured to the face shield. This and other implementations can each optionally include one or more of the following features

In some implementations, the mount includes a first plate and a second plate. The first plate is mounted above the transparent face shield and external to the full-face mask. The second plate is mounted inside the full-face mask and coupled to a frame of the full-face mask by a plurality of couplers. The second plate is coupled to the first plate through the frame by a plurality of fasteners, where the fasteners form a thermal path for conducting heat generated by the visual display system to the first plate. The chassis is suspended from the second plate.

In some implementations, the chassis is suspended from the second plate by a drive screw and a guide rod, where the guide rod is configured to conduct thermal energy from the electronic circuitry to the fasteners in the second plate.

In some implementations, the fasteners in the second plate are configured to conduct thermal energy to the first plate.

In some implementations, the visual display system includes a printed circuit board (PCB), one or more light sources, liquid-crystal-on-silicon (LCOS) displays, and partial reflectors enclosed in a metal housing. The PCB includes a protruding edge in physical contact with and electrically grounded to the metal housing.

In some implementations, the chassis is suspended from and vertically movable relative to the mount via a drive screw.

In some implementations, the drive screw engages with a nut made from a self-lubricating material.

In some implementations, the drive screw has four or more threads.

In some implementations, the drive screw has eight threads.

In some implementations, the respirator is connected to an oxygen or purified-air supply hose.

In some implementations, the display optics include light sources, liquid-crystal-on-silicon (LCOS) displays, partial reflectors, and combiners configured to combine light received through the face shield with an image from the LCOS displays along optical axes aligned, when in use, with the user's eyes.

In some implementations, the display optics includes stretched-film reflective polarizers in a path between the light sources and the LCOS displays.

In some implementations, the chassis includes holes serving as alignment features during assembly of the device and as venting paths during use of the device.

Another general aspect can be embodied in a device that includes a full-face mask, a visual display system, and a visual display controller. The full-face mask is configured to seal against a user's face, when in use, to form a mask cavity, and the mask includes a transparent face shield and a built-in respirator connected to an oxygen or purified-air supply hose. The visual display system is placed inside the mask cavity and includes display optics and electronic circuitry held in a chassis. The visual display controller is mounted on the oxygen or purified-air supply hose. The visual display controller includes a plurality of user input elements for user control of the visual display system. These and other implementations can each optionally include one or more of the following features.

In some implementations, the user input elements include a display switch, a power switch, and brightness adjustment buttons.

In some implementations, the user input elements include at least one of tactile or haptic distinguishing features.

In some implementations, the visual display controller includes one or more LED indicators each includes an associated crossed-polarizer dimmer.

In some implementations, the device includes a triaxial cable connected to the electronic circuitry to provide power, control signals, video data to the visual display system.

In some implementations, the triaxial cable includes braided wires surrounding a microcoaxial cable.

In some implementations, the device a video converter connected to the electronic circuitry via the triaxial cable, where the video converter is configured to convert a video feed into a gigabit serial link signal.

In some implementations, the device includes a coaxial cable connected to the electronic circuitry to provide power, control signals, video data to the visual display system. The coaxial cable includes an outer radio frequency (RF) shield, where the outer RF shield is connected to ground.

The details of these and other aspects are set forth in the accompanying drawings and the description below. Other features, objects, and advantages will be apparent from the description and drawings, and from the claims.

### DESCRIPTION OF DRAWINGS

FIGS. 1A and 1B illustrate an example face mask with an internal display system and controller.

FIG. 2 is a front view of an internal display and mounting system for a face mask.

FIG. 3 is a side view of an internal display and mounting system for a face mask.

FIG. 4 is an illustration of mounting plates for an in-mask display system

FIGS. 5A and 5B show a partial schematic view of an in-mask display system illustrating some optical components from a front view, and a top perspective view.

FIG. 6 is diagram illustrating an optical flow path of an in-mask display system.

FIG. 7A is a front facing illustration of a mask in a storage box with an exposed controller.

FIG. 7B is a side facing illustration of a mask in a storage box with an exposed controller.

FIGS. 8A and 8B show perspective illustrations of exemplary connectors used to connect the internal plate of the mounting system to the face mask.

FIG. 9 is a perspective view of a face mask with the internal plate of a display mounting system attached.

### DETAILED DESCRIPTION

This disclosure describes a display and mounting system for a display to be integrated into a positive pressure mask. In certain enclosed environments, emergency masks are used as a backup source of breathable atmosphere in the event the regular atmosphere becomes unusable. For example, a fire in an aircraft can rapidly render the internal volume of the aircraft unsuitable for breathing. In these instances, emergency masks can be provided which form a seal with the user's face and provide an independent breathable atmosphere. For example, an MF20-004 mask is a full-face, positive pressure, oxygen mask that allows the user to breathe independently of the ambient atmosphere. While the mask may enable breathing, smoke or other environmental factors may inhibit visibility. In the aircraft example, it may be imperative that a pilot have access to certain information (e.g., airspeed, attitude, altitude, etc.) even when visibility in the cockpit is obstructed. This disclosure provides an in-mask display, and mounting system to provide critical information to the user, regardless of visibility external to the mask.

Since the in-mask display is located near the user's eyes (within the mask) it should be adjustable to conform to users with different facial structures. A mechanism is provided to allow the display to be translated vertically within the mask, allowing the user to align the display with their eyes. The display must also be mounted in a manner that minimizes mask penetrations (and therefore possible leak points) and conducts heat generated by the display outside of the mask.

While the present disclosure describes the in-mask display system in the context of an aircraft pilot's mask, the disclosed displays system is also useful for masks used in other contexts. For example, the in-mask display system described herein can be incorporated into other sealed face masks e.g., firefighter masks or dive masks.

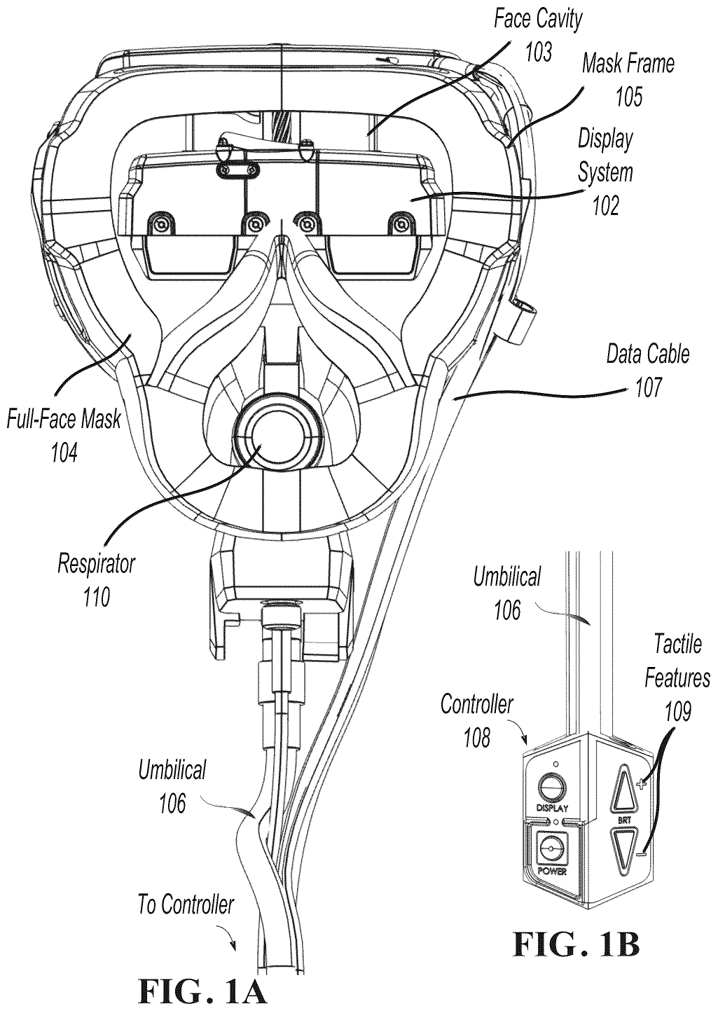

FIGS. 1A and 1B illustrate an example face mask 104 with an internal display system 102 and controller 108. Full face mask 104 includes a seal that surrounds the eyes, nose and mouth of a user, and prevents or reduces gas exchange between an environment inside the mask and the outside environment. In some implementations, full face mask 104 is an MF20-004 mask. An umbilical 106 delivers a pressurized gas supply (e.g., compressed air, or oxygen) that pressurizes the inside of the mask. The breathable gas supply can be provided to a respirator 110, which can control flow of the gas at demand of a user's breath. In some implementations, exhaust valves near the top of the mask (not shown) allow excess gas (e.g., exhaled gas from the user) to escape the mask, while ensuring outside gasses do not infiltrate into the mask. In addition to delivering pressurized, breathable, gas, the umbilical 106 can include one or more data cables 107, carrying communications and/or electrical power to control systems associated with the mask and/or the display system 102.

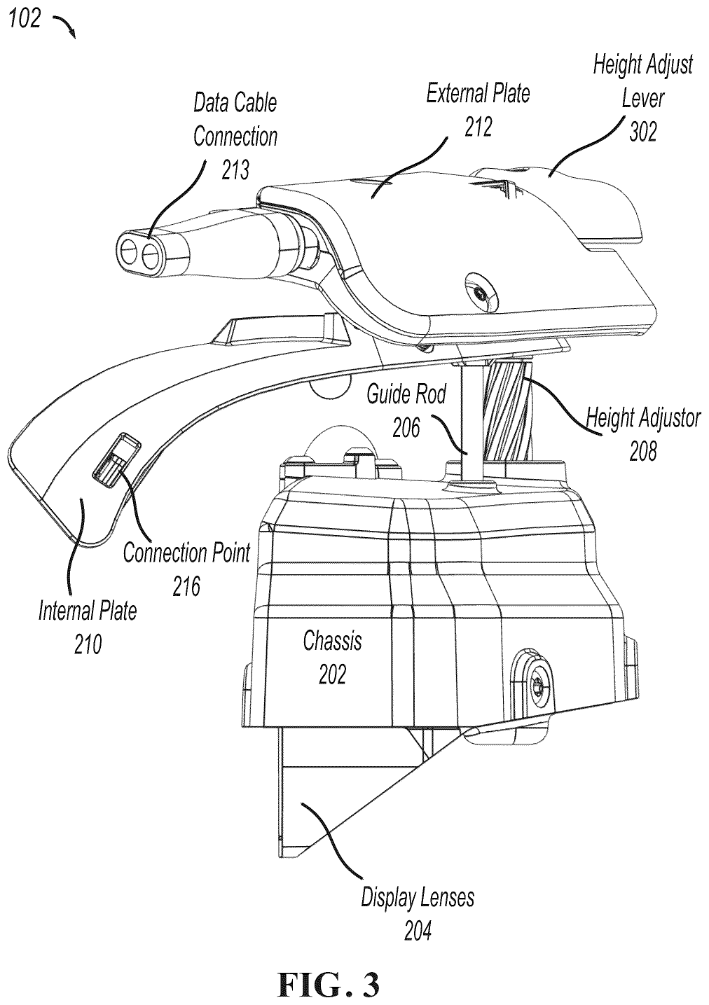

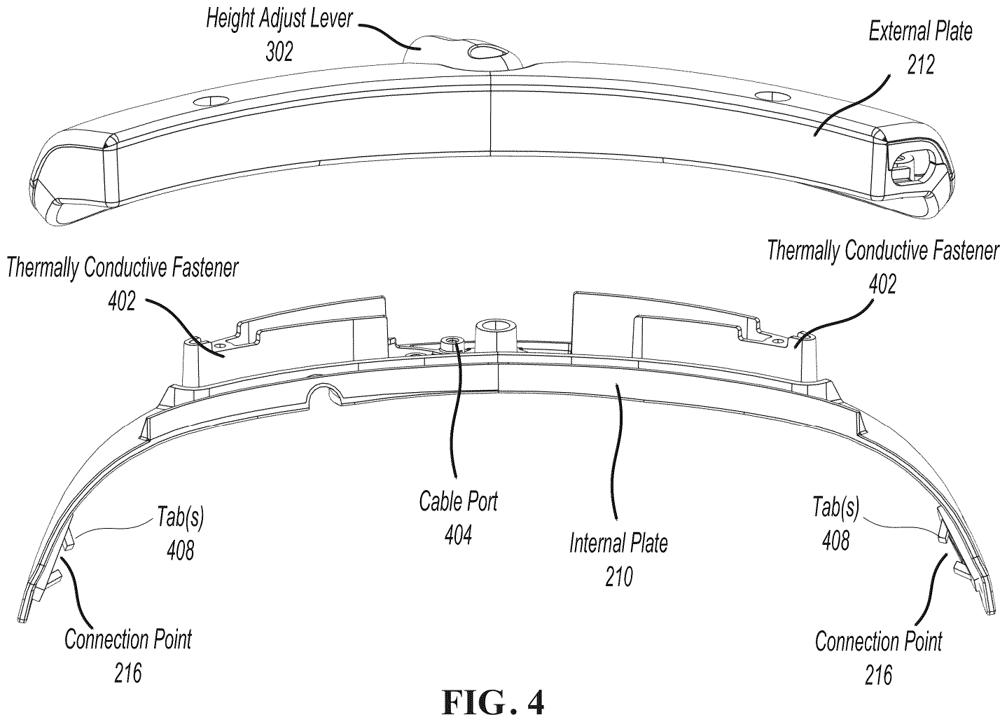

Display system 102 is mounted inside a cavity 103 of the mask, and can be configured to be positioned in front of the user's eyes. For example, the cavity 103 may be formed between the face shield (shown as 904 in FIG. 4) of the face-mask and the user. In the illustrated example, display system 102 is a transparent heads-up display (HUD) which displays images, data or both, while also allowing the user to see through the display. In some implementations, the display system 102 can be a solid screen, with see-through is provided using an external (e.g. forward facing) camera. In some implementations, display system 102 may be positioned only over a single eye of the user. The display system 102 is height adjustable, permitting the user to align it with their eyes. Height adjustment is discussed in greater detail below with regard to FIG. 3. Together the face mask 104 and display system 102, with controller 108, are configured to weigh less than 2.3 pounds.

In some implementations, a controller 108 is provided to permit the user to interact with the display system 102. The illustrated controller 108 in FIG. 1B includes several user controls including, but not limited to, a power button, display button, and brightness increase and decrease buttons. The user controls are generally physical, tactile input elements and can include push buttons, rocker switches, membrane switches, rotary switches, slide switches, toggle switches. The display button can be used to cycle through various menus or options within a graphical user interface in the display system 102. In some implementations the controller 108 includes more, or fewer controls than what are illustrated in FIG. 1B. Additionally, controls on controller 108 are not limited to buttons. The controls can include toggles, knobs, dials, touchscreens, or other input devices. In some implementations, the controls can include tactile features 109 on or near the controls that distinguish one control button/switch from another. For example, the controller 108 illustrated in FIG. 1B depicts embossed “+” and “−” symbols next to the brightness control buttons.

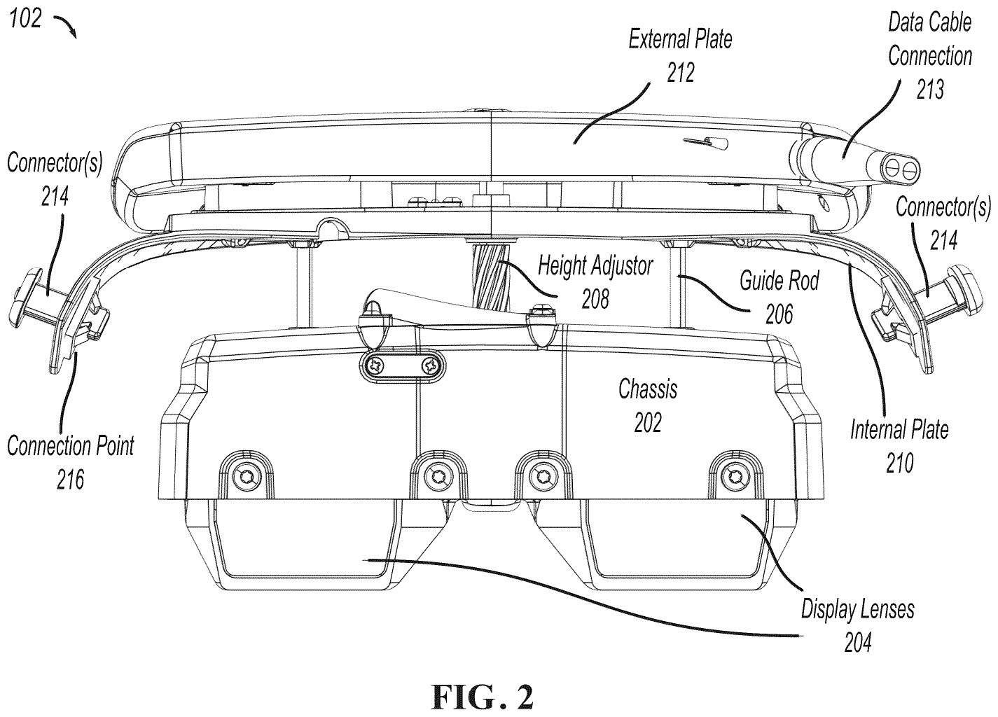

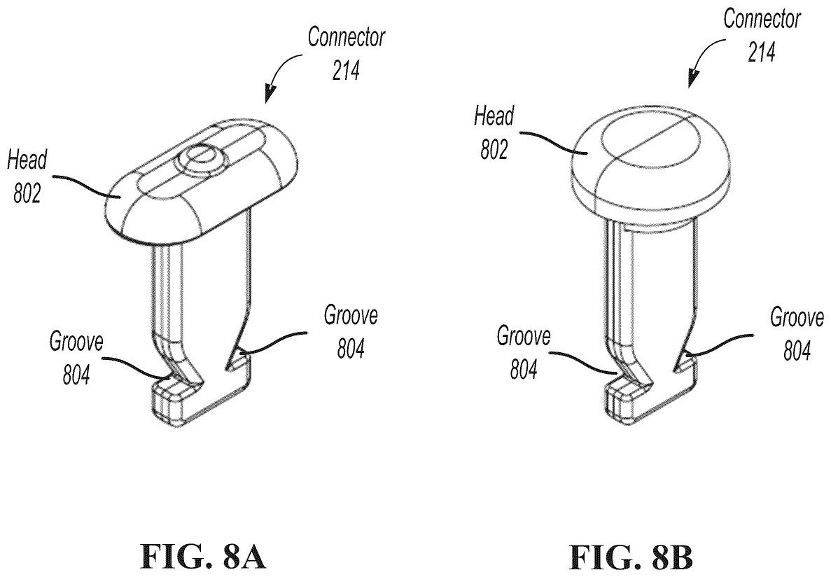

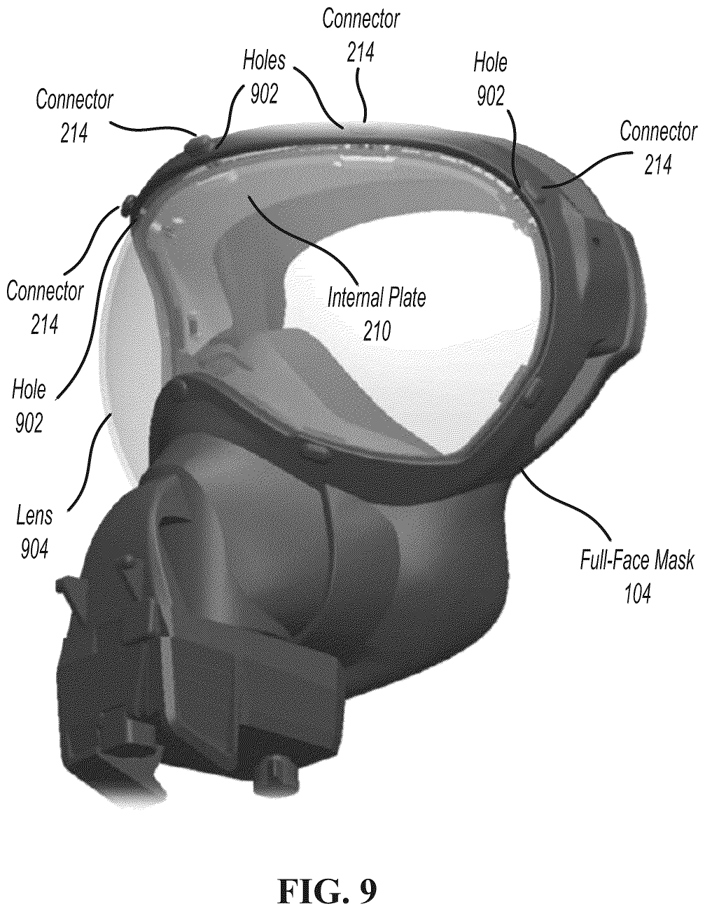

FIG. 2 is a front view of an internal display and mounting system for a face mask. The display system 102 includes a chassis 202 that is suspended from an internal plate 210 by a height adjuster 208 and one or more guide rods 206. The internal plate 210 mounts on the inside of the mask to the external plate 212, which is outside of the mask. The internal plate 210 can be mounted to the mask frame 105 through one or more sealed penetrations, or other fastening devices. The internal plate 210 couples to the inside of the face mask 104 using connectors 214. FIGS. 8A and 8B show perspective illustrations of exemplary connectors 214. The connectors 214 attached to the internal plate 210 at connection points 216. Connectors 214 include a head 802 configured to connect to the inside of the face mask frame 105 and groove (e.g., a half-dovetail) 804 configured to interface with corresponding tabs 408 (shown in FIG. 4) located at connection points 216. For example, connectors 214 are passed through existing rivet holes 902 in the face mask 104 and clip to the connection points 216 on the internal plate 210 (shown in FIG. 9). The external plate 212 and internal plate 210 can be screwed together at the top with an existing silicone seal of the face mask 104 in between. The silicone seal may serves as an ingress protection. As described in greater detail below and with reference to FIG. 4, the internal plate 210 can provide for heat transfer from the chassis 202 to the external plate 212.

External plate 212 can be mounted to the internal plate 210, outside of the seal of the mask, and can include electronics and other components necessary to operate the display system 102. Some implementations, include electronic components in the external plate 212 which generate significant heat or use larger voltages/currents. The inside of the mask can be a pure oxygen environment, and so to avoid sparking or other flammability concerns, certain circuitry can be included in the external plate 212 outside of the mask. In some implementations, video and/or telemetry data from external to the mask (e.g., from an aircraft) is provided via the umbilical (e.g., umbilical 106 as described with reference to FIG. 1) to circuitry in the external plate 212 where it is converted to a low power, proprietary format to be transmitted into the mask via a single cable (e.g., a tri-axial cable). In certain instances, the video and/or telemetry data is provided via one or more data cables 107 of the umbilical 106 in a low power, proprietary format and need not be converted by the display system 102 until it is rendered to the display lenses 204. External plate 212 can include a data cable connection 213, which can connect to a data cable (e.g., data cable 107 of FIG. 1).

The chassis 202 houses additional circuitry for generating images on the display lenses 204. It is suspended from the internal plate 210 via a height adjustor 208. The height adjustor 208 can be implemented as a worm gear that is rotatably mounted to the internal plate 210. When the height adjustor 208 rotates, its threads engage with channels in the chassis 202 causing the entire chassis 202 to translate up or down depending on the direction of rotation. In some implementations, the height adjustor 208 engages with, or is formed of a self-lubricating material (e.g., a high density polyethylene) which reduces wear and risk of spark or arc. In some implementations, the height adjustor 208 is an 8 toothed worm gear. For example, an 8-toothed worm gear provides significant vertical displacement of the chassis 202 with minimal rotation (e.g., approximately 45 degrees of rotation provides approximately 1-2 inches of vertical displacement). Other implementations, can include a height adjustor with 4-10 teeth.

Guide rods 206 are provided to ensure the chassis 202 stays aligned with the user's face as it translates, and to assist in conducting heat from the chassis 202 to the internal plate 210. The chassis 202 can include a shroud, or outer shell, which generally encloses the additional circuitry and at least a portion of the display lenses 204. In some implementations the shroud includes an aluminum alloy that is beneficial for heat transfer from internals of the display system 102, as well as reduction in electromagnetic interference (EMI). In certain instances, the shroud is an anodized aluminum alloy. In some implementations, the shroud is a magnesium alloy. Heat generating components inside the chassis 202 can be thermally coupled to the shroud to encourage rapid heat dissipation and transfer out of the display system 102.

The display lenses 204 receive an image and redirect it toward the user's eyes. In some implementations, the display lenses also allow external light to pass through, providing the projected image as an overlay to what the user would normally see.

FIG. 3 is a side view of an internal display and mounting system for a face mask. In the side view, a high adjust lever 302 is visible. The height adjust lever 302 allows the user to manually rotate the height adjustor 208, and align the display lenses 204 with their eyes. In some implementations, the height adjustment can be automatic, and a sensor (e.g., a camera) in the chassis 202 can detect the location of the user's eyes and automatically rotate the height adjustor 208 to align with the detected eye location.

FIG. 4 is an illustration of mounting plates for an in-mask display system. The internal plate 210 and the external plate 212 are configured to sandwich a frame of the mask. In certain instances the plates are screwed together with sealed screws at penetrations in the mask seal. In some implementations, the penetrations are used as exhaust for the positive pressure environment inside the mask.

The external plate 212 can be formed of an aluminum alloy, and act as a heat sink for thermal energy generated in the display system (e.g., display system 102 of FIG. 1). In some implementations, external plate 212 includes fins, channels, or other surface area enhancing features (not shown) which improve the plate's ability to transfer heat away from the mask.

The internal plate 210 includes thermally conductive fasteners 402. The thermally conductive fasteners 402 can mount to the external plate 212 and provide good heat transfer between the internal plate 210 and the external plate 212. In certain instances, the thermally conductive fasteners 402 are an aluminum alloy, a ceramic material, graphite, carbon impregnated rubber material, or other material with high thermal conductivity. In the illustrated example, the thermally conductive fasteners 402 include a threaded slot underneath (not shown) where a guide rod (e.g., guide rod 206 of FIG. 2) can be threaded. The thermally conductive guide rod provides a thermal path from the display system, through the guide rod and thermally conductive fastener 402 to the external plate 212.

Internal plate 210 can include a cable port 404, which allows a data and communications cable (e.g., triaxial cable) to pass from the external plate 212 through the internal plate 210 to the display system. The cable port 404 can include packing material, or one or more seals to reduce or prevent gas passing through the cable port 404. In some instances a single, combined data and power cable passes from the umbilical through the external plate 212 and internal plate 210 to the display system. The cable can transmit a low-power, signal for images or video. For example the cable can transmit a gigabit serial link data which allows high-speed, high-bandwidth, two way communication using a single, EMI resistant cable. The cable can be, for example, a triaxial cable or a coaxial cable with additional braided wires surrounding the coaxial cable. In some implementations the cable includes multiple twisted pairs. In some implementations, the cable includes an outer radio frequency (RF) shield coupled to ground.

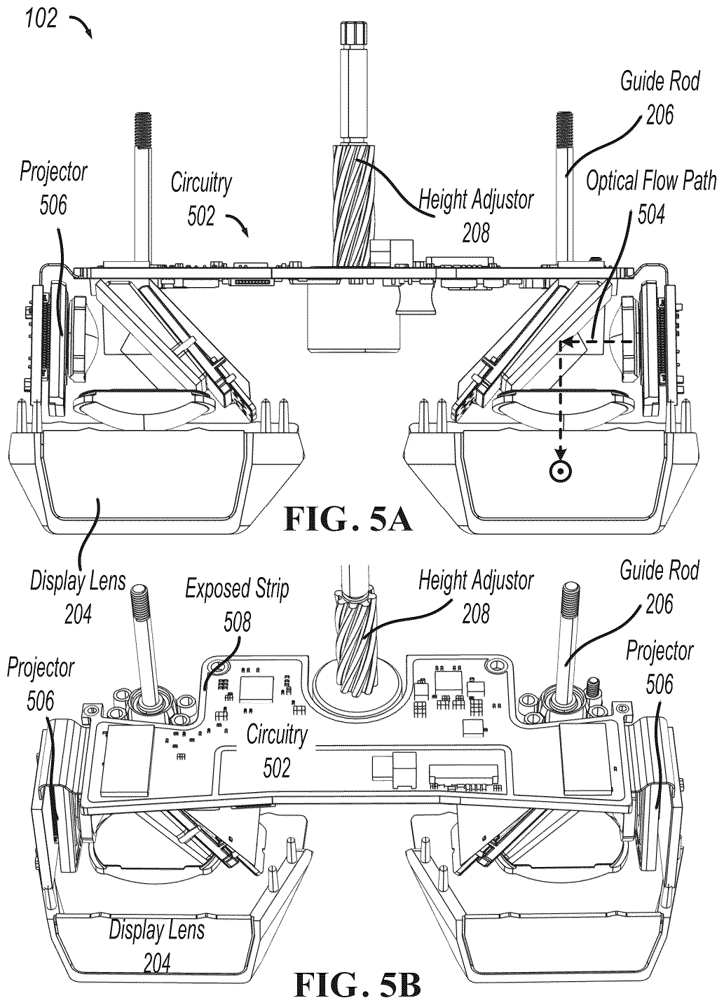

FIGS. 5A and 5B show a partial schematic view of an in-mask display system illustrating some components from a front view, and a top perspective view. The in-mask display system 102 includes circuitry 502, which converts signals received in the cable into an optical image to be projected to the user's eyes. Circuitry 502 can include, but is not limited to, projectors 506, display buffer storages, voltage regulators, a serializer/deserializer chip for multiplexing and de-multiplexing gigabit serial link signals, microcontroller units, or other integrated circuit components. The circuitry 502 can be provided on one or more printed circuit boards (PCBs). In the illustrated example, three PCBs are provided, one for each projector and a central PCB including other components (display buffers, voltage regulators, the serializer/deserializer chip, microcontrollers, etc.).

The central PCB includes an exposed strip 508 in the illustrated example which can be in electrical contact with a shroud of the chassis, ensuring the display system and structural components are electrically grounded. The exposed strip 508 can form a protruding edge from the rest of the PCB, and make physical contact with the shroud. Heat generating components in circuitry 502 can be thermally coupled to the shroud (e.g., via heat pipes, thermal paste, or other connection) and the shroud can be in contact with the guide rods, providing a thermal connection from the circuitry 502, to the external plate 216 as discussed above.

The projectors 506 each include one or more displays, LED backlights, and one or more lenses for projecting an image onto the optical flow path 504. The optical flow path 504 is a path in which the projected image takes from the projector, through one or more lenses, and reflecting off one or more reflectors to the user's eyes. The displays in the projectors 506 can be liquid crystal on silicon (LCOS) displays. LCOS displays are advantageous in that they can have a small form factor, and relatively low power consumption compared to other projector displays.

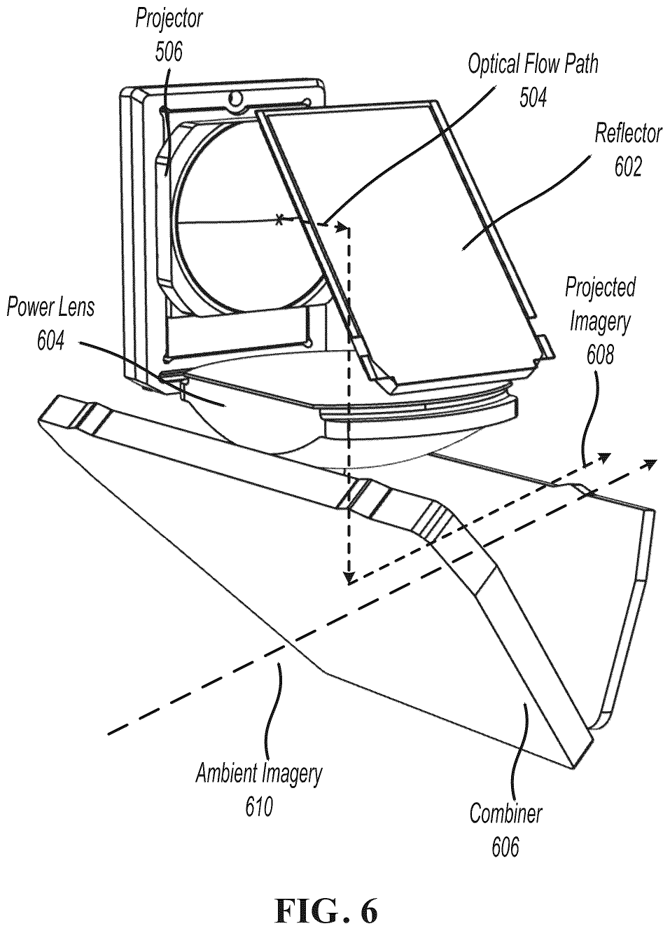

FIG. 6 is diagram illustrating an example optical flow path of an in-mask display system. The projector 506 generates an optical image which travels along the optical flow path 504 to one or more reflectors 602, which reflect the optical image down to a power lens 604. Power lens 604 collimates and focuses the optical image into the combiner 606, which reflects the projected optical image as projected energy 608 to the user's eyes. Additionally the combiner 606 allows ambient imagery 610 to pass through, combining with the projected imagery 608 in order to provide a HUD style display to the user, where the projected image is overlaid with what the user sees through the front of the mask.

In some implementations, the reflector 602 can be a stretched film polarizer. Stretched film polarizers are a type of reflective polarizer. Due to the properties of using an LCOS, which initially encodes the image in polarization state, some element in the optical path must have a polarization dependent property, so that the polarized image light is separated from the non-image light (e.g., ambient imagery 610). The stretched film polarizer achieves this need, while being easier to manufacture, and far less fragile, compared to alternatives.

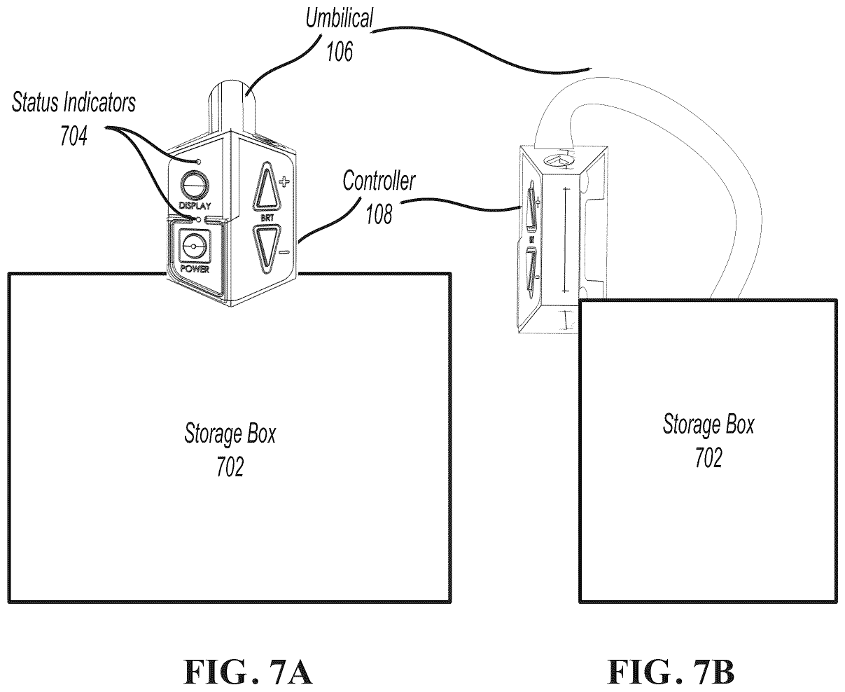

FIGS. 7A and 7B are an illustration of a mask in a storage box with an exposed controller. In some instance, routine maintenance and liveness checks need to be performed on the mask and in-mask display. The mask can be stored in a storage box 702, with the controller mounted to a front of the box. In some implementations, the controller is stored within the box, but positioned so its face is visible from outside the box. Providing for maintenance without removing the mask from its storage box 702 reduces wear and prolongs life of the mask, as well as reduces maintenance time.

The controller 108 can include one or more status indicators 704, which can be LED lights or other indicators that indicate, for example, battery charge, data connectivity, or other important factors to ensure the mask and in-mask display are ready to operate. In some implementations, the LED indicators have an associated crossed-polarizer dimmer. For example, the crossed-polarizer dimmer(s) may be used to reduce the brightness of the LED light output.

1. A visual display mounting system configured for mounting a visual display system inside full-face masks, the visual display mounting system comprising:
a mount comprising a first plate and a second plate configured to be attached to a full-face mask, the first plate configured to be attached externally to a top of the full-face mask, the second plate shaped to fit inside the full-face mask, wherein the first plate and second plate are configured to be coupled one to the other through a frame of the full-face mask; and
a chassis configured to be suspended from the second plate, when installed in the full-face mask, the chassis supporting display optics and electronic circuitry of the visual display system.

2. The system of claim 1, wherein the chassis is suspended from the second plate by a drive screw and a guide rod, wherein the guide rod is configured to conduct thermal energy from the electronic circuitry to a fastener in the second plate.

3. The system of claim 2, wherein the fastener in the second plate is configured to conduct thermal energy to the first plate.

4. The system of claim 2, wherein the visual display system comprises a printed circuit board (PCB), one or more light sources, liquid-crystal-on-silicon (LCOS) displays, and partial reflectors enclosed in a metal housing, the PCB comprising a protruding edge in physical contact with and electrically grounded to the metal housing.

5. A device comprising:
a full-face mask configured, when in use, to seal against a user's face to form a mask cavity, the mask comprising a built-in respirator and a transparent face shield; and
a visual display system placed inside the mask cavity, the visual display system comprising display optics and electronic circuitry held in a chassis, the chassis suspended from a mount secured to the face shield.

6. The device of claim 5, wherein the mount comprises:
a first plate mounted above the transparent face shield and external to the full-face mask; and
a second plate mounted inside the full-face mask and coupled to a frame of the full-face mask by a plurality of couplers, the second plate coupled to the first plate through the frame by a plurality of fasteners, the fasteners forming a thermal path for conducting heat generated by the visual display system to the first plate, the chassis being suspended from the second plate.

7. The device of claim 6, wherein the chassis is suspended from the second plate by a drive screw and a guide rod, wherein the guide rod is configured to conduct thermal energy from the electronic circuitry to the fasteners in the second plate,
wherein fasteners in the second plate are configured to conduct thermal energy to the first plate, and
wherein the visual display system comprises a printed circuit board (PCB), one or more light sources, liquid-crystal-on-silicon (LCOS) displays, and partial reflectors enclosed in a metal housing, the PCB comprising a protruding edge in physical contact with and electrically grounded to the metal housing.

8. The device of claim 5, wherein the chassis is suspended from and vertically movable relative to the mount via a drive screw.

9. The device of claim 8, wherein the drive screw engages with a nut made from a self-lubricating material.

10. The device of claim 8, wherein the drive screw comprises four or more threads.

11. The device of claim 10, wherein the drive screw comprises eight threads.

12. The device of claim 5, wherein the respirator is connected to an oxygen or purified-air supply hose.

13. The device of claim 5, wherein the display optics include light sources, liquid-crystal-on-silicon (LCOS) displays, partial reflectors, and combiners configured to combine light received through the face shield with an image from the LCOS displays along optical axes aligned, when in use, with the user's eyes.

14. The device of claim 13, wherein the display optics further comprises stretched-film reflective polarizers in a path between the light sources and the LCOS displays.

15. The device of claim 5, wherein the chassis comprises holes serving as alignment features during assembly of the device and as venting paths during use of the device.

16. A device comprising:
a full-face mask configured, when in use, to seal against a user's face to form a mask cavity, the mask comprising a transparent face shield and a built-in respirator connected to an oxygen or purified-air supply hose;
a visual display system placed inside the mask cavity, the visual display system comprising display optics and electronic circuitry held in a chassis; and
a visual display controller mounted on the oxygen or purified-air supply hose, the visual display controller comprising a plurality of user input elements for user control of the visual display system.

17. The device of claim 16, wherein the user input elements comprise a display switch, a power switch, and brightness adjustment buttons.

18. The device of claim 16, wherein the user input elements comprise at least one of tactile or haptic distinguishing features.

19. The device of claim 16, wherein the visual display controller comprises one or more LED indicators each comprising an associated crossed-polarizer dimmer.

20. The device of claim 16, further comprising a triaxial cable connected to the electronic circuitry to provide power, control signals, video data to the visual display system.

21. The device of claim 20, wherein the triaxial cable comprises braided wires surrounding a microcoaxial cable.

22. The device of claim 20, further comprising a video converter connected to the electronic circuitry via the triaxial cable, the video converter configured to convert a video feed into a gigabit serial link signal.

23. The device of claim 16, further comprising a coaxial cable connected to the electronic circuitry to provide power, control signals, video data to the visual display system, the coaxial cable comprising an outer radio frequency (RF) shield, wherein the outer RF shield is connected to ground.
